(19) United States
(12) Patent Application Publication
(10) Pub. No.: US 2006/0158224 A1
(43) Pub. Date: Jul. 20, 2006

(54) Output driver with feedback slew rate control

(75) Inventor: Luo Yan-Bin, Taipei City (TW)

Correspondence Address: DUANE MORRIS, LLP;IP DEPARTMENT, 30 SOUTH 17TH STREET, PHILADELPHIA, PA, 19103-4196, US

(73) Assignee: Elite Semiconductor Memory Technology, Inc.

(21) Appl. No.: 11/075,085

(22) Filed: Mar. 8, 2005

Related U.S. Application Data
(60) Provisional application No. 60/643,968, filed on Jan. 14, 2005.

(51) Int. Cl. H03K 19/094

(52) U.S. Cl. 326/87

(57) ABSTRACT

An output driver circuit comprises a primary output driver and a secondary output driver, where the primary and secondary output drivers have outputs at an output terminal and inputs at an input terminal. A slew rate control circuit is provided for disabling the secondary output driver in response to a signal at the output terminal

### CROSS-REFERENCE TO RELATED APPLICATIONS

The present application claims priority to U.S. Provisional Patent Application No. 60/643,968 filed Jan. 14, 2005 and entitled “Output Driver with Feedback Slew Rate Control,” the entirety of which is hereby incorporated by reference herein.

### FIELD OF THE INVENTION

The present invention relates to output drivers, and more particularly output drivers having slew rate control.

### BACKGROUND OF THE INVENTION

In high speed parallel I/O bus systems, fast bus drivers must have controlled output slew rates to ensure good signal integrity, i.e., slew rates that are controlled under certain conditions. Controlling the slew rate provides three advantages. First, the self-induced L di/dt switching noise of the integrated circuit (IC) is reduced. Briefly, there are two inductances coupled to the voltage source and ground within the IC. The switch current will cause internal power bounce, i.e. ΔVdd=L di/dt. This effect will increase the output timing jitter and degrade the signal integrity. Second, transmission line effects of the printed circuit board (PCB) traces are reduced by controlling the slew rate. Reflection, which is a transmission line effect due to impedance mismatch at source or load to transmission line, needs to be considered to reserve the signal integrity. Third, controlling the slew rate can reduce electromagnetic interference.

FIG. 1 is a circuit diagram of a prior art CMOS output driver 10 without slew rate control. In one known embodiment, the output transistors Mp1 and Mn1 are designed for high drive current capability and, as such, turn on with very fast slew rates. An embodiment of this prior art circuit with transistors having lower drive current capability, i.e., using smaller transistors, has a slower slew rate. Failure to control the slew rate, however, of the driver can lead to the problems outline above.

One prior art output driver having slew rate control is proposed in U.S. Pat. No. 6,441,653 to Spurlin. Spurlin provides a CMOS output driver having a DC feedback circuit that changes the output impedance of the driving transistors as the output voltage transition progresses. The output voltage slew rate is controlled by limiting the gate voltage of the output driver transistors during transition. In one embodiment, the slew rate control is provided by a fairly complex feedback circuit and resistor divider using matched resistors to limit and control the output transistor gate drive during output signal transitions.

Therefore, there remains a need for an improved output driver circuit having slew rate control that is simple and cost effective.

### SUMMARY OF THE INVENTION

An output driver circuit comprises a primary output driver and a secondary output driver, where the primary and secondary output drivers have outputs at an output terminal and inputs at an input terminal. A slew rate control circuit is provided for disabling the secondary output driver in response to a signal at the output terminal.

The above and other features of the present invention will be better understood from the following detailed description of the preferred embodiments of the invention that is provided in connection with the accompanying drawings.

### BRIEF DESCRIPTION OF THE DRAWINGS

The accompanying drawings illustrate preferred embodiments of the invention, as well as other information pertinent to the disclosure, in which:

FIG. 1 is a circuit diagram of a prior art output driver;

FIG. 2 is a circuit diagram of an output driver having slew rate control;

FIG. 3 is a plot of the pull down I/V curve of a simulation of the output driver circuit of FIG. 2 and two prior art output driver circuits;

FIG. 4 is a plot of the pull-up I/V curve of a simulation of the circuit of FIG. 2 and two prior art output driver circuits;

FIG. 5 is a plot illustrating the rise and fall times observed from a simulation of the circuit of FIG. 2 and two prior art output driver circuits;

FIGS. 6(a)-6(c) are eye diagram plots of the driver output from a simulation of the circuit of FIG. 2 and two prior art output driver circuits; and

FIGS. 7(a)-7(c) are eye diagram plots of the output at a simulated load coupled to the circuit of FIG. 2 and two prior art output driver circuits.

### DETAILED DESCRIPTION

FIG. 2 is circuit diagram of an improved CMOS output driver 20. Output driver 20 may be disposed as part of integrated circuit 5. Output driver 20 has a signal input node Vi and a signal output node Vo and a first supply terminal 24 coupled to supply voltage V_{DD} and a second supply terminal 26 coupled to ground. In one embodiment, output driver 20 comprises a primary output driver, a secondary output driver and a slew rate control circuit, each of which is described in more detail below. As described below, the slew rate control circuit advantageously slows the slew rate (i.e., reduces the amount of current available to drive the output, as the output approaches steady state.

The primary CMOS output driver includes first pull-up PMOS transistor Mp1 and first pull-down NMOS transistor Mn1. The control terminals of each of these transistors are coupled to input node Vi, optionally through respective inverters 22. First pull-up transistor Mp1 is coupled between the first supply terminal 24 and the output node Vo. First pull-down transistor Mn1 is coupled between the output node Vo and the second supply terminal 26.

The secondary CMOS output driver includes second pull-up PMOS transistor Mp2 and second pull-down NMOS transistor Mn2. The control terminals of each of these transistors are also coupled to input node Vi, optionally through respective inverters 22. Second pull-up transistor Mp2 is also coupled between the first supply terminal 24 and the output node Vo, but through a slew rate control circuit as described below. Likewise, second pull-down transistor Mn2 is also coupled between the second supply terminal 26 and the output node Vo, but through the slew rate control circuit.

In one embodiment, the slew rate control circuit includes first slew rate control transistor Mpa, which is a PMOS transistor, and second slew rate control transistor Mna, which is an NMOS transistor, each having control terminals coupled to output node Vo. The first slew rate control transistor Mpa is coupled between the first supply terminal 24 and the second pull-up transistor Mp2, and the second slew rate control transistor Mna is coupled between the second supply terminal 26 and the second pull-down transistor Mn2.

In one embodiment, the primary output driver has a weaker drive capability than the secondary output driver. The width and channel length of transistors determine their current carrying capacity. For VDD equal to 2.5 V, exemplary driver transistors have the following dimensions or geometries in microns (width/channel length): Mn1 (80/0.25); Mp1 (240/0.25); Mn2 (160/0.25); and Mp2 (480/0.25). In this embodiment, exemplary slew rate transistors have the following dimensions: Mna (640/0.25); and Mpa (1920/0.25). As described below, the primary output driver fully switches on throughout the output voltage transition. However, the secondary output driver is selectively disabled during a part of the output voltage transition and at steady state (i.e., output voltage high (V_{DD}) and low condition (0V)) in response to a feedback signal from the voltage output Vo.

Assume initially that Vi and Vo are both in the low state, i.e., 0V or ground, and that the gate-to-source voltage (V_{GS}) of first slew rate control transistor Mpa is more that the threshold voltage Vtp of Mpa. When Vi transitions from the low to the high state (i.e., V_{DD}), both first and second pull-up transistors Mp1 and Mp2 are “on” to pull-up the load Vo. The primary output driver is always on. While Vo is less than V_{DD}−Vtp, both the primary and secondary output drivers operate to pull-up the load, as first slew rate control transistor Mpa is on. However, when Vo exceeds a first voltage threshold V_{DD}−VtP, first slew rate control transistor Mpa switches off, thereby disabling the pull-up transistor Mp2 of secondary output driver, leaving only the primary output driver pull-up transistor Mp1 to drive the load thereafter and during the steady state.

Conversely, assume initially that Vi and Vo are both in the high state, i.e., V_{DD}, and that the gate-to-source voltage (V_{GS}) of second slew rate control transistor Mna is more that the threshold voltage Vtn of Mna. When Vi transitions from the high to the low state (i.e., ground), both first and second pull-down transistors Mn1 and Mn2 are “on” to pull-down the load Vo. The primary output driver is always on. While Vo is greater than Vtn, both the primary and secondary output drivers operate to pull-down the load, as the second slew rate control transistor Mna is on. However, when Vo falls below a second voltage threshold Vtn, second slew rate control transistor Mna switches off, thereby disabling the second pull-down transistor Mn2 of the secondary output driver, leaving only the primary output driver pull-down transistor Mn1 to drive the load thereafter and during the steady state.

While Vo is less than Vtn at falling edge and greater than Vdd−Vtp at rising edge, the secondary output driver, which has stronger drive capability than the primary output driver, will be disabled. This mechanism decreases output driver current and also decrease the switching current at power (VDD) and ground (GND). The selective decrease in driving/switching current can reduce the self-induced Ldi/dt switching noise and electromagnetic interference.

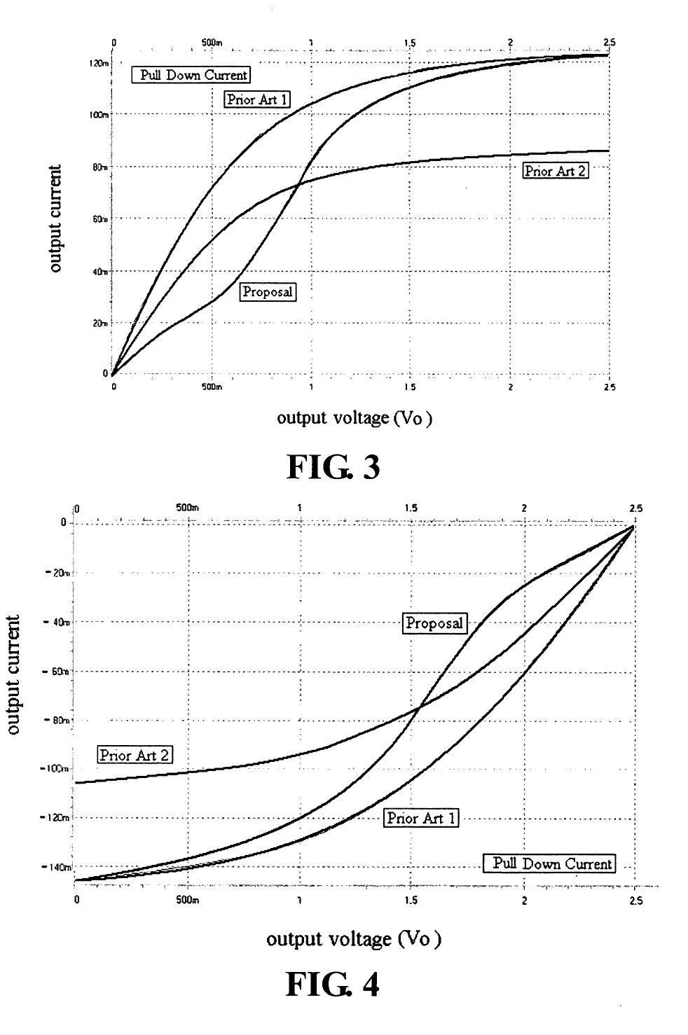

Further, when the secondary output driver is disabled, the output impedance of the output driver circuit 20 is larger than when the secondary output driver is enabled. The impedance transformation can be seen from FIGS. 3-4. Output impedance is 1/(Slope of the I-V curve). At the steady state, i.e., near the origin of the I-V curve, the output driver 20 shows greater impedance than both Prior Art 1 and Prior Art 2. Because the secondary output driver is disabled at the steady state, i.e., when Vo is at ground or at V_{DD}, then the output impedance of the output driver circuit 20 is high during the steady state. With prior art circuits, due to the output driver consuming a lot of current during the data transitions, this instantaneous large consumptive current results in an on-chip power voltage fluctuation. And, the smaller impedance connected from on-chip power or ground to the output nodes results in bigger signal bounce because of Resistor/Inductor/Capacitor circuitry damping effects. Providing high output impedance during the steady state helps to reduce signal bounce from the package bonding wire inductance to output capacitance loads and transmission line trace reflection.

Still further, selective enabling of the secondary driver controls the slew rate of the output driver. The secondary driver, which has a larger drive capability than the primary output driver, is enabled during the input low-to-high and high-to-low transitions to help drive the output transitions. As the transition approaches steady state (i.e., as the output voltage exceeds V_{DD}−VtP or falls below Vtn), and at steady state, the secondary driver is disabled, thereby reducing overdrive current provided to the output load. It also suppresses the output overshoot or undershoot voltage to decrease damage possibilities for the device receiving the output signal.

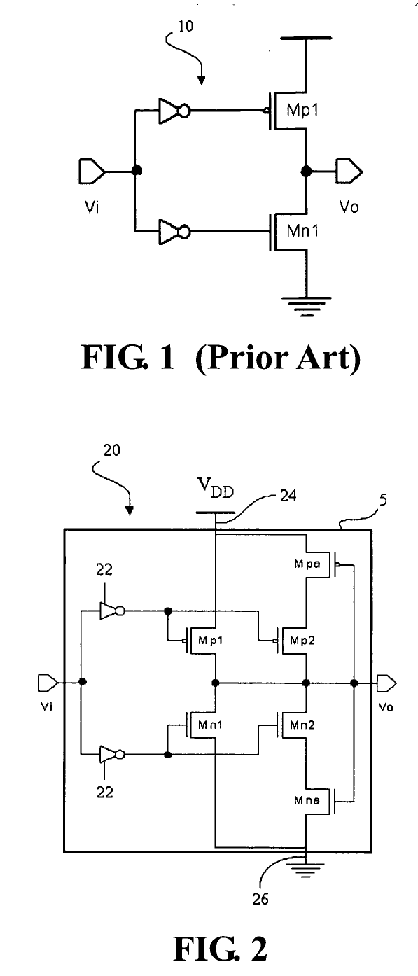

FIGS. 3-7 illustrate simulation results for three output driver circuits simulated using SPICE models. A first simulated output driver circuit (labeled “Proposal” in the figures) is the output driver circuit 20 of FIG. 2 and having the transistor sizes provided above. Two prior art output drivers circuits without slew rate control were also tested. The first output driver circuit, which is referenced as “Prior Art 1” in the figures, is the output driver circuit 10 of FIG. 1. In this simulation, the output driver circuit was provided with high drive capability transistors. Specifically, the dimensions for Mn1 and Mp1 in this simulation were as follows: Mn1 (240/0.25); and Mp1 (720/0.25)). The second simulated prior art output driver circuit (referenced as “Prior Art 2” in the figures) was identical to Prior Art 1, although using transistors having less drive capability. Specifically, the dimensions for Mn1 and Mp1 in the simulation were as follows: Mn1 (160/0.25); and Mp1 (480/0.25). In summary, these simulations show that the proposed output driver circuit 20 has roughly the same drive capability as Prior Art 1, but with controlled slew rate and has better signal integrity than Prior Arts 1 and 2.

FIGS. 3 and 4, respectively, are the “pull down” and “pull-up” I/V curves for the simulated output drivers. These I/V curves plot output current versus the output voltage (Vo) when the output driver drives a simulated 50 Ω, 35 ps delay transmission line with 30 pf capacitor and 500 Ω resistor shunted to ground. These I/V curves provide the information of the output drive capability and output impedance transformation. The output driver circuit 20 has almost the same drive current as prior art I but has larger impedance at the steady state as shown at and/or near the origin of I/V curves. The output impedance is the 1/(Slope of I/V curve) as described above.

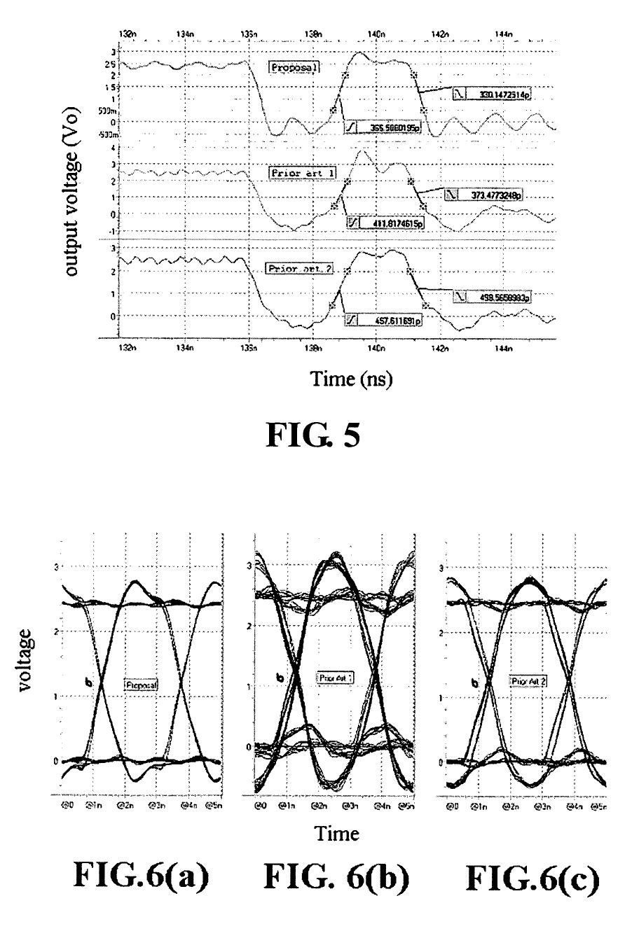

FIG. 5 is a plot showing the rise and fall times of the simulated drivers. The rise time, defined for purposes of the simulation as the rise time between 500 mv to 2.0 volts, and the fall time, defined for purposes of the simulation as the fall time between 2.0 volts and 500 mv, were observed to be improved over both simulated prior art circuits. The rise and fall times for the output driver circuit 20 were approximately 367 and 330 ps, respectively. The rise and fall times for the Prior Art 1 output driver were approximately 412 and 373 ps, respectively. The rise and fall times for the Prior Art 2 output driver were approximately 468 and 499 ps, respectively.

FIGS. 6(a), 6(b) and 6(c) show eye diagram plots at the driver outputs of the three simulated circuits. These diagrams show that the overshoot and jitter for the output driver circuit 20 are less than the two simulated prior art designs. The amplitude of points a and c are the overshoot and undershoot respectively. The width of cross-point b is the jitter. The output driver circuit 20 exhibits better (i.e., shorter) overshoot/undershoot amplitude and jitter width.

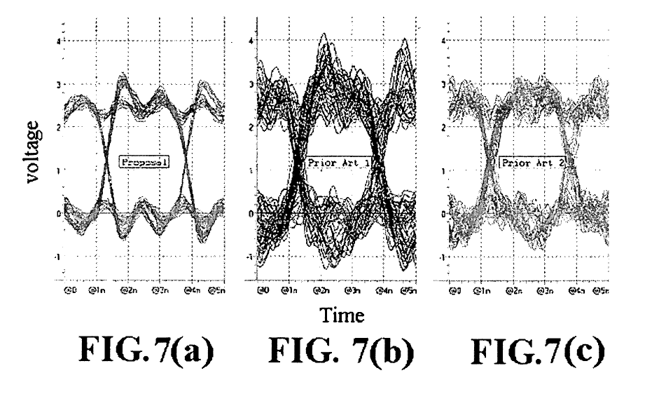

FIGS. 7(a), 7(b) and 7(c) show eye diagram plots at the simulated load, i.e., at the simulated 30 pf and 500 Ω load, coupled to the three simulated output driver circuits. These diagrams show that the output driver circuit 20 can provide clearer eye pattern than the Prior Art 1 and 2. In essence, the output driver circuit 20 can provide better signal quality to system loads.

From the foregoing, it should be apparent that the improved output driver circuit 20 having slew rate control advantageously controls the slew rate to reduce self-induced Ldi/dt switching noise, reduced transmission line effects of a printed circuit board (PCB) trace and reduce electromagnetic interference. Also, with respect to the prior art driver circuit of FIG. 1 described above, the output driver circuit 20 has a faster slew rate over the output signal transition range.

In some embodiments, the output driver circuit 20 can be used in high-speed data or clock output drivers, such as data bus I/O application, memory interface and clock distribution applications.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention

What is claimed is:

1. An output driver circuit, comprising:
a primary output driver;
a secondary output driver, said primary and secondary output drivers having outputs at an output terminal and inputs at an input terminal; and
a slew rate control circuit for disabling the secondary output driver in response to a signal at said output terminal.

2. The output driver circuit of claim 1,
wherein said primary output driver comprises:
a first pull-up output transistor coupled between a first supply terminal and said output terminal, the first pull-up output transistor having a control terminal coupled to said input terminal; and
a first pull-down output transistor coupled between a second supply terminal and said output terminal, the first pull-down output transistor having a control terminal coupled to said input terminal; and
wherein said secondary output driver comprises:
a second pull-up output transistor coupled between said first supply terminal and said output terminal, the second pull-up output transistor terminal having a control terminal coupled to said input terminal; and
a second pull-down output transistor coupled between said second supply terminal and said output terminal, the second pull-down output transistor having a control terminal coupled to said input terminal.

3. The output driver circuit of claim 2, wherein said slew rate control circuit comprises:
a first slew rate control transistor coupled between said second pull-up output transistor and said first supply terminal, said first slew rate control transistor having a control terminal coupled to said output terminal; and
a second slew rate control transistor coupled between said second pull-down output transistor and said second supply terminal, said second slew rate control transistor having a control terminal coupled to said output terminal.

4. The output driver circuit of claim 3, wherein said first slew rate control transistor comprises a PMOS transistor and said second slew rate control transistor comprises an NMOS transistor.

5. The output driver circuit of claim 2, wherein said secondary output driver has a stronger drive capability than said primary output driver.

6. The output driver circuit of claim 5, wherein said second pull-up output transistor is larger than said first pull-up output transistor and wherein said second pull-down output transistor is larger than said first pull-down output transistor.

7. The output driver circuit of claim 1, wherein said slew rate control circuit comprises:
a first slew rate control transistor coupled between said secondary output driver and a first supply terminal, said first slew rate control transistor having a control terminal coupled to said output terminal; and
a second slew rate control transistor coupled between said secondary output driver and a second supply terminal, said second slew rate control transistor having a control terminal coupled to said output terminal.

8. The output driver circuit of claim 7,
wherein said primary output driver comprises a first CMOS driver coupled between said first and second supply terminals and having an input coupled to the input terminal and an output coupled to said output terminal; and
wherein said secondary output driver comprises a second CMOS driver coupled between said first and second supply terminals and having an input coupled to said input terminal and an output coupled to said output terminal.

9. The output driver of claim 8, wherein said first slew rate control transistor comprises a PMOS transistor and said second slew rate control transistor comprises an NMOS transistor.

10. The output driver of claim 1, wherein said secondary output driver has a stronger drive capability than said primary output driver.

11. A CMOS output driver circuit, comprising:
a primary CMOS output driver having an input coupled to an input terminal and an output coupled to an output terminal;
a secondary CMOS output driver having an input coupled to said input terminal and an output coupled to said output terminal, said secondary CMOS output driver having greater drive capability than said primary CMOS output driver; and
a slew rate control circuit, said slew rate control circuit having circuitry for disabling said secondary CMOS output driver responsive to an output at said output terminal, wherein the output impedance of said CMOS output driver circuit is increased at a steady state voltage condition.

12. The CMOS output driver circuit of claim 11, wherein the slew rate control circuit includes means for disabling said secondary CMOS output driver at a high steady state voltage condition and means for disabling said secondary CMOS output driver at a low steady state voltage condition.

13. The CMOS output driver circuit of claim 12, wherein said disabling means disables said secondary CMOS output driver when said output is above a first voltage threshold below said high steady state condition but above said low steady state condition, and disables said secondary CMOS output driver when said output is below a second voltage threshold, said second voltage threshold being greater than said low steady state voltage and below said first voltage threshold.

14. The CMOS output driver circuit of claim 11,
wherein said primary and secondary CMOS output drivers are coupled between first and second supply terminals, and
wherein said slew rate control circuit comprises:
a first slew rate control transistor coupled between said secondary output driver and a first supply terminal, said first slew rate control transistor having a control terminal coupled to said output terminal; and
a second slew rate control transistor coupled between said secondary output driver and a second supply terminal, said second slew rate control transistor having a control terminal coupled to said output terminal.

15. The CMOS output driver circuit of claim 14, wherein said first slew rate control transistor comprises a PMOS transistor and said second slew rate control transistor comprises an NMOS transistor.

16. The CMOS output driver of claim 11, wherein each of said output drivers comprise a pull-up output transistor and a pull-down output transistor, wherein said pull-up output transistor of said secondary output driver is larger than said pull-up output transistor of said first output driver, and said pull-down output transistor of said secondary output driver is larger than said pull-down output transistor of said first output driver.

17. A method of output driving with slew rate control, comprising the steps of:
driving an output signal at an output terminal in response to an input signal at an input terminal with a CMOS output driver circuit comprising a primary CMOS output driver and a secondary CMOS output driver; and
in response to said output signal, selectively disabling said secondary output driver to change the output impedance of said CMOS output driver circuit, whereby the slew rate of the CMOS output driver circuit is controlled during transition of said output signal.

18. The method of claim 17, wherein said secondary output driver has greater drive capability than said primary output driver.

19. The method of claim 17, wherein said secondary CMOS output driver is disabled when said output signal is above a first voltage threshold that is below a high steady state voltage condition, and when said output signal is below a second voltage threshold, said second voltage threshold being greater than a low steady state voltage condition but below said first voltage threshold.
